(19) United States
(12) Patent Application Publication
(10) Pub. No.: US 2013/0240958 A1
(43) Pub. Date: Sep. 19, 2013

(54) SEMICONDUCTOR STRUCTURE AND METHOD FOR FORMING THE SAME

(71) Applicants: Jing Wang, Beijing (CN); Lei Guo, Beijing (CN); Wei Wang, Beijing (CN)

(72) Inventors: Jing Wang, Beijing (CN); Lei Guo, Beijing (CN); Wei Wang, Beijing (CN)

(21) Appl. No.: 13/521,051

(22) PCT Filed: May 29, 2012
(86) PCT No.: PCT/CN12/76240

§ 371 Date: Jul. 8, 2012

(30) Foreign Application Priority Data
Mar. 13, 2012 (CN) 201210065893.9
May 22, 2012 (CN) 201210161250.4

(51) Int. Cl. H01L 29/78; H01L 21/336

(52) U.S. Cl. 257/288; 438/285; 438/299; 257/E29.255; 257/E21.409

(57) ABSTRACT

A semiconductor structure and a method for forming the same are provided. The semiconductor structure comprises: a semiconductor substrate; an active region formed in the semiconductor substrate, in which the active region comprises: a channel region, and a source region and a drain region formed on both sides of the channel region respectively; and a first isolation trench formed in the semiconductor substrate and on both sides of the active region, in which a first rare earth oxide layer is formed in each first isolation trench to produce a stress in the channel region in a channel length direction.

### CROSS-REFERENCE TO RELATED APPLICATIONS

This application claims priority to and benefits of the following applications:
1) Chinese Patent Application Serial No. 201210065893.9, filed with the State Intellectual Property Office of P. R. China on Mar. 13, 2012; and
2) Chinese Patent Application Serial No. 201210161250.4, filed with the State Intellectual Property Office of P. R. China on May 22, 2012.

The entire contents of the above applications are incorporated herein by reference.

### FIELD

The present disclosure relates to semiconductor design and fabrication field, and more particularly to a semiconductor structure and a method for forming the same.

### BACKGROUND

By producing a corresponding stress in a specific region of a semiconductor device according to a device type thereof, a carrier mobility of the device may be raised, thus improving a performance of the device. In a deep submicron or nanometer device, a suitable stress is important to improve the performance of the device. Conventional methods for producing a stress comprises: adding a substitutional element in a source region and a drain region to change a lattice constant by epitaxial growth or ion implantation, or depositing a stress cap layer after forming a device structure, etc. One of the most primary disadvantages of these conventional methods lies in difficulty in adjusting stress type and complicated process.

A trench isolation is a common process step in a method for fabricating the semiconductor device, which means isolating adjacent active regions by using an insulating material. Conventional materials for filling in a trench as isolation generally comprise an oxide or nitride of a semiconductor substrate material, such as silicon dioxide or silicon nitride. A conventional method for forming the isolation area with the above materials filled therein is mostly filling the insulating material in a trench by a physical method, which is complicated in process. Therefore, it is hard to ensure the stability and uniformity of the filling. In the prior art, another method for producing the stress is to make use of a difference between thermal expansion coefficients of the conventional insulating material filled in the trench and a semiconductor substrate material to produce the stress in a channel region. However, the stress produced by this method is generally too small to form an effective tension or compression to the channel region, and thus it is hard to significantly improve the performance of the semiconductor device.

### SUMMARY

The present disclosure is aimed to solve at least one of the problems, particularly a problem of difficulty in producing a stress from a trench isolation, complicated process and undesirable stress effect.

According to an aspect of the present disclosure, a semiconductor structure is provided. The semiconductor structure comprises: a semiconductor substrate; an active region formed in the semiconductor substrate, in which the active region comprises: a channel region, and a source region and a drain region formed on both sides of the channel region respectively; and a first isolation trench formed in the semiconductor substrate and on both sides of the active region in a channel length direction, in which a first rare earth oxide layer is formed in each first isolation trench to produce a stress in the channel region in the channel length direction.

In one embodiment, a material of the semiconductor substrate comprises single crystal silicon (Si), single crystal germanium (Ge), silicon-germanium (SiGe), or any group III-V compound semiconductor.

In one embodiment, a thickness of the first rare earth oxide layer is within a range from 10 nm to 500 nm. In a trench isolation process of the semiconductor device, a thickness of an isolation trench may be properly adjusted according to a feature size of the device, that is, a too small thickness may cause an isolation between active regions to be not effective enough so as to result in a failure of the device, while a too large thickness may cause excess dislocations in the rare earth oxide layer so as to allow the stress produced in the channel region by the rare earth oxide layer to be released, increase process difficulties, such as difficulties in trench formation and filling in an isolation region, and increase a cost.

In one embodiment, a second isolation trench is formed in the semiconductor substrate and on both sides of the active region in a channel width direction. A common isolation dielectric, such as silicon oxide or silicon nitride, may be filled in the second isolation trench. Preferably, a second rare earth oxide layer may be formed in each second isolation trench to produce a stress in the channel region in the channel width direction. Depending on the type of the device, the stress produced in the channel region by the second rare earth oxide layer and the stress produced in the channel region by the first rare earth oxide layer may be identical or opposite in stress type so as to enhance an improvement effect of stresses.

In one embodiment, a material of each of the first rare earth oxide layer and the second rare earth oxide layer comprises any one of (Gd₁₋ₓErₓ)₂O₃, (Gd₁₋ₓNdₓ)₂O₃, (Er₁₋ₓNdₓ)₂O₃, (Pr₁₋ₓLaₓ)₂O₃, (Pr₁₋ₓNdₓ)₂O₃, (Pr₁₋ₓGdₓ)₂O₃, (Er₁₋ₓLaₓ)₂O₃, Er₂O₃, Gd₂O₃, Nd₂O₃, Pr₂O₃, La₂O₃ and a combination thereof, where x is within a range from 0 to 1.

In one embodiment, the first rare earth oxide layer and the second rare earth oxide layer are formed by epitaxial growth.

According to another aspect of the present disclosure, a method for forming a semiconductor structure is provided. The method comprises steps of: providing a semiconductor substrate; forming an active region in the semiconductor substrate, in which the active region comprises: a channel region, and a source region and a drain region formed on both sides of the channel region respectively; and before or after forming the active region, forming a first trench in the semiconductor substrate and on both sides of the active region in a channel length direction, and forming a first rare earth oxide layer in each first trench to produce a stress in the channel region in the channel length direction.

In one embodiment, a material of the semiconductor substrate comprises single crystal silicon, single crystal germanium, silicon-germanium, or any group III-V compound semiconductor.

In one embodiment, a thickness of the first rare earth oxide layer is within a range from 10 nm to 500 nm. In a trench isolation process of the semiconductor device, a thickness of an isolation trench may be properly adjusted according to a feature size of the device, that is, a too small thickness may cause an isolation between active regions to be not effective enough so as to result in a failure of the device, while a too large thickness may cause excess dislocations in the rare earth oxide layer so as to allow the stress produced in the channel region by the rare earth oxide layer to be released, increase process difficulties, such as difficulties in trench formation and filling in an isolation region, and increase a cost.

In one embodiment, before or after forming the active region, the method further comprises: forming a second isolation trench in the semiconductor substrate and on both sides of the active region in a channel width direction; and forming an isolation layer in each second isolation trench. A material of the isolation layer may be a common isolation dielectric, such as silicon oxide or silicon nitride. Preferably, the isolation layer may comprise a second rare earth oxide layer to produce a stress in the channel region in the channel width direction. Depending on the type of device, the stress produced in the channel region by the second rare earth oxide layer and the stress produced in the channel region by the first rare earth oxide layer may be identical or opposite in stress type so as to enhance an improvement effect of stresses.

In one embodiment, a material of each of the first rare earth oxide layer and the second rare earth oxide layer comprises any one of (Gd₁₋ₓErₓ)₂O₃, (Gd₁₋ₓNdₓ)₂O₃, (Er₁₋ₓNdₓ)₂O₃, (Pr₁₋ₓLaₓ)₂O₃, (Pr₁₋ₓNdₓ)₂O₃, (Pr₁₋ₓGdₓ)₂O₃, (Er₁₋ₓLaₓ)₂O₃, Er₂O₃, Gd₂O₃, Nd₂O₃, Pr₂O₃, La₂O₃ and a combination thereof, where x is within a range from 0 to 1.

In one embodiment, the first rare earth oxide layer and the second rare earth oxide layer are formed by epitaxial growth.

In one embodiment, the epitaxial growth comprises atomic layer deposition (ALD), metal-organic chemical vapor deposition (MOCVD) and molecular beam epitaxy (MBE).

With the semiconductor structure and the method for forming the same according to an embodiment of the present disclosure, the rare earth oxide layer is formed in the trench isolation region of the semiconductor device as an isolation structure. A lattice constant of a rare earth oxide is about two times as large as that of commonly used semiconductor materials such as Si, Ge, and group III-V compound semiconductor materials. By adjusting a element and a constituent of the rare earth oxide, the lattice constant thereof may be conveniently adjusted to be slightly larger or smaller than twice that of each of a material of the channel and the material of the semiconductor substrate, thus producing the stress in a specific region of the semiconductor device during an epitaxial growth process of the rare earth oxide because of a lattice constant difference. Advantages of the present disclosure are listed as follows.

(1) Because the lattice constant of the rare earth oxide is varied with a type and a content of a rare earth element in the rare earth oxide, by adjusting the element and the constituent of the rare earth oxide, a required stress may be produced in the channel region.

(2) Because a stress source of the semiconductor structure is obtained by crystal growth, compared with a conventional trench isolation structure, the stress produced in the channel region is larger, and a carrier mobility of the device may be more significantly and effectively raised.

(3) By using a crystal characteristic of the rare earth oxide, a conventional and complicated method for filling an insulating material may be replaced by the crystal growth, thus greatly simplifying a process flow.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIG. 1 is a cross-sectional view of a semiconductor structure according to an embodiment of the present disclosure;

FIG. 2 is a top view of a semiconductor structure according to another embodiment of the present disclosure;

FIG. 3 is a flow chart of a method for forming a semiconductor structure according to an embodiment of the present disclosure;

FIG. 4 is a schematic view of lattice structures of a first rare earth oxide layer and a side wall of a first trench of a semiconductor structure formed by a method according to a first embodiment of the present disclosure; and

FIG. 5 is a schematic view of lattice structures of a first rare earth oxide layer and a side wall of a first trench of a semiconductor structure formed by a method according to a second embodiment of the present disclosure.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

It is to be understood that phraseology and terminology used herein with reference to device or element orientation (such as, terms like “longitudinal”, “lateral”, “front”, “rear”, “right”, “left”, “lower”, “upper”, “horizontal”, “vertical”, “above”, “below”, “up”, “top”, “bottom” as well as derivative thereof such as “horizontally”, “downwardly”, “upwardly”, etc.) are only used to simplify description of the present invention, and do not alone indicate or imply that the device or element referred to must have or operated in a particular orientation.

With the semiconductor structure according to an embodiment of the present disclosure, a rare earth oxide layer is formed in a trench isolation region of a semiconductor device as an isolation structure, thus producing a stress in a specific region (such as a channel region) of the semiconductor device. FIG. 1 is a cross-sectional view of a semiconductor structure according to an embodiment of the present disclosure. As shown in FIG. 1, the semiconductor structure comprises: a semiconductor substrate 100, an active region formed in the semiconductor substrate 100, which comprises: a channel region 200, and a source region 300 and a drain region 400 formed on both sides of the channel region 200 respectively; and a first isolation trench 500 formed in the semiconductor substrate 100 and on both sides of the active region in a channel length direction, in which a first rare earth oxide layer 502 is formed in each first isolation trench 500 to produce the stress in the channel region 200 in the channel length direction (as shown by an arrow L in FIG. 1).

In one embodiment, a material of the semiconductor substrate 100 comprises single crystal silicon, single crystal germanium, silicon-germanium, or any group III-V compound semiconductor.

In one embodiment, a material of the first rare earth oxide layer 502 comprises any one of (Gd₁₋ₓErₓ)₂O₃, (Gd₁₋ₓNdₓ)₂O₃, (Er₁₋ₓNdₓ)₂O₃, (Pr₁₋ₓLaₓ)₂O₃, (Pr₁₋ₓNdₓ)₂O₃, (Pr₁₋ₓGdₓ)₂O₃, (Er₁₋ₓLaₓ)₂O₃, Er₂O₃, Gd₂O₃, Nd₂O₃, Pr₂O₃, La₂O₃ and a combination thereof, where x is within a range from 0 to 1. Because a lattice constant of the rare earth oxide is varied with a type and a content of a rare earth element in the rare earth oxide, by adjusting the element and the constituent of the rare earth oxide, a tunable stress may be produced in the channel region 200 based on a requirement of the device type, that is, the type and the intensity of stress in the channel region 200 may be adjusted.

In one embodiment, a thickness of the first rare earth oxide layer 502 is within a range from 10 nm to 500 nm. In a trench isolation process of the semiconductor device, a thickness of an isolation trench may be properly adjusted according to a feature size of the device, that is, a too small thickness may cause an isolation between active regions to be not effective enough so as to result in a failure of the device, while a too large thickness may cause excess dislocations in the rare earth oxide layer so as to allow the stress produced in the channel region by the rare earth oxide layer to be released, increase process difficulties, such as difficulties in trench formation and filling in an isolation region, and increase a cost.

In a preferred embodiment, the first rare earth oxide layer 502 is formed by epitaxial growth, such as atomic layer deposition, metal-organic chemical vapor deposition and molecular beam epitaxy. Because a stress source (i.e., the first rare earth oxide layer 502) of the semiconductor structure is obtained by crystal growth, compared with a conventional trench isolation structure, the stress produced in the channel region is larger, and a carrier mobility of the device may be more significantly and effectively raised.

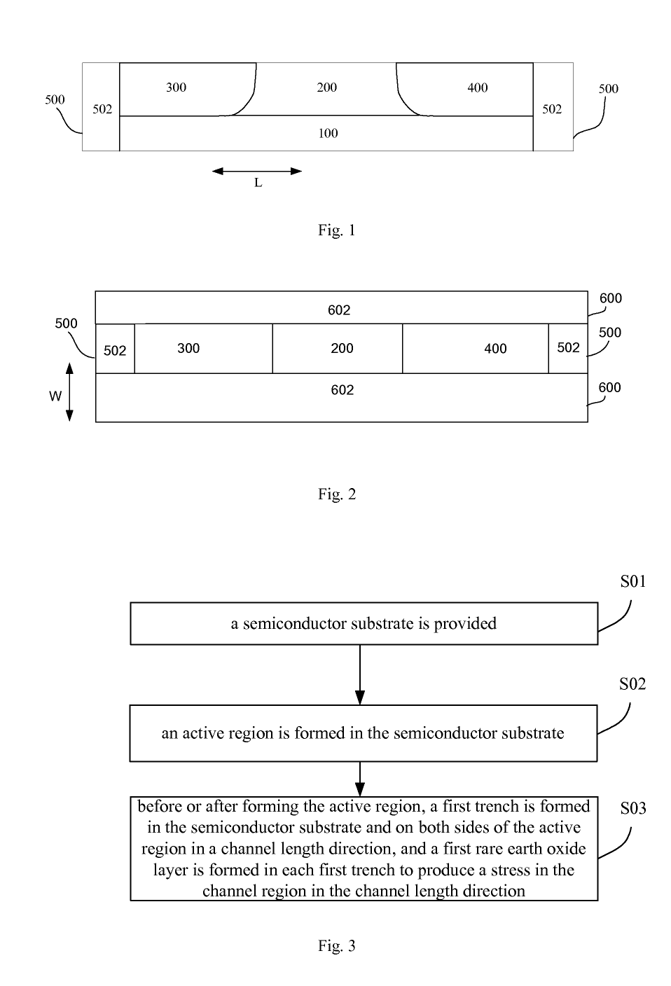

FIG. 2 is a top view of a semiconductor structure according to a preferred embodiment of the present disclosure. Based on the semiconductor structure shown in FIG. 1, the semiconductor structure shown in FIG. 2 further comprises: a second isolation trench 600 formed in the semiconductor substrate 100 and on both sides of the active region in a channel width direction (as shown by an arrow W in FIG. 2). A common isolation dielectric, such as silicon oxide or silicon nitride, may be filled in each second isolation trench 600. Preferably, a second rare earth oxide layer 602 may be formed in each second isolation trench 600 to produce a stress in the channel region 200 in the channel width direction. Depending on the type of the device, the stress produced in the channel region 200 by the second rare earth oxide layer 602 and the stress produced in the channel region 200 by the first rare earth oxide layer 502 may be identical or opposite in stress type so as to enhance an improvement effect of stresses. For example, if the channel material is silicon, the material of the first rare earth oxide layer 502 in each first isolation trench 500 may be (Gd₁₋ₓErₓ)₂O₃ to produce a tensile stress in the channel region 200, and the material of the second rare earth oxide layer 602 in each second isolation trench 600 may be Nd₂O₃ to produce a compressive stress in the channel region 200.

According to another aspect of the present disclosure, a method for forming a semiconductor structure is provided. FIG. 3 is a flow chart of the method for forming a semiconductor structure according to an embodiment of the present disclosure. The method comprises following steps.

Step S01: a semiconductor substrate is provided. In one embodiment, a material of the semiconductor substrate comprises single crystal silicon, single crystal germanium, silicon-germanium, or any group III-V compound semiconductor.

Step S02: an active region is formed in the semiconductor substrate. The active region comprises: a channel region, and a source region and a drain region formed on both sides of the channel region respectively. It should be noted that in some embodiments, a structure, a material and a forming method of the active region are not specifically restricted, but any active region existing in the prior art or to be appeared in future may be applied.

Step S03: before or after forming the active region, a first trench is formed in the semiconductor substrate and on both sides of the active region in a channel length direction, and a first rare earth oxide layer is formed in each first trench to produce a stress in the channel region in the channel length direction. Specifically, a trench isolation region is predetermined in the semiconductor substrate and on both sides of the active region, and then each first trench is formed by etching each trench isolation region. A depth of each first trench may be determined according to an isolation requirement, which is generally matched with a width of the channel region. An achievement of an isolation effect and a production of the stress in the channel region are used as criterions to determine a thickness of the first rare earth oxide layer in each first trench. Preferably, for a convenience of subsequent processes, the thickness of the first rare earth oxide layer is substantially identical with the depth of each first trench. Because the depth of each first trench and the thickness of the first rare earth oxide layer are determined according to a feature size of a specific semiconductor device, based on the feature size of a current semiconductor device, each of the depth of each first trench and the thickness of the first rare earth oxide layer may be within a range from 10 nm to 500 nm. For example, if the depth of the channel region of a device is 60 nm, the depth of each first trench and the thickness of the first rare earth oxide layer may be within a range from 50 nm to 200 nm, preferably 60 nm.

In a preferred embodiment, the first rare earth oxide layer is formed by epitaxial growth, such as atomic layer deposition, metal-organic chemical vapor deposition and molecular beam epitaxy. Because a stress source (i.e. the first rare earth oxide layer) of the semiconductor structure is obtained by crystal growth, compared with a conventional trench isolation structure, the stress produced in the channel region is larger, and a carrier mobility of the device may be more significantly and effectively raised. Moreover, by using a crystal characteristic of the rare earth oxide, a conventional and complicated method for filling an insulating material may be replaced by the crystal growth, thus greatly simplifying a process flow. Because a lattice constant of the rare earth oxide is varied with a type and a content of a rare earth element in the rare earth oxide, by adjusting the element and the constituent of the rare earth oxide, a tunable stress may be produced in the channel region based on a requirement of the device type, that is, the type and the intensity of stress in the channel region may be adjusted.

In one embodiment, before or after forming the active region, the method further comprises: forming a second isolation trench in the semiconductor substrate and on both sides of the active region in the channel width direction; and forming an isolation layer in each second isolation trench. A material of the isolation layer may be a common isolation dielectric, such as silicon oxide or silicon nitride. Preferably, the isolation layer may comprise a second rare earth oxide layer to produce a stress in the channel region in the channel width direction. Depending on the type of the device, the stress produced in the channel region by the second rare earth oxide layer and the stress produced in the channel region by the first rare earth oxide layer may be identical or opposite in stress type so as to enhance an improvement effect of stresses. For example, if the channel material is silicon, the material of the first rare earth oxide layer may be (Gd₁₋ₓErₓ)₂O₃ to produce a tensile stress in the channel region, and the material of the second rare earth oxide layer may be Nd₂O₃ to produce a compressive stress in the channel region.

The semiconductor structure formed by ALD and MOCVD crystal growth methods are described below in details in two embodiments respectively.

### Embodiment 1

Step S101: a semiconductor substrate is provided. In this embodiment, a material of the semiconductor substrate may be single crystal silicon.

Step S102: a trench isolation region is predetermined in the semiconductor substrate and on both sides of the active region in a channel length direction, and then each first trench is formed by etching each trench isolation region. A depth of each first trench is determined according to an isolation requirement, which is generally matched with a width of the channel region. In this embodiment, the channel region and the first trench may be 60 nm in depth.

Step S103: a first rare earth oxide layer is filled in each first trench by ALD. According to a proportion of a rare earth oxide in a required product, with a corresponding rare earth element as a rare earth element source and with water or ozone as a reactant, the rare earth oxide is grown at a temperature ranging from 200° C. to 400° C. for a suitable time to form the first rare earth oxide layer in each first trench. Preferably, the first rare earth oxide layer is formed in each first trench by epitaxial growth. In this embodiment, with (CpMe)₃Er and Gd(OCMe₂CH₂OMe)₃ with a suitable ratio as the rare earth element sources and with H₂O as the reactant, the rare earth oxide are grown by ALD at a temperature of 250° C., and after 600 cycles, the first rare earth oxide layer (Gd₁₋ₓErₓ)₂O₃ with a thickness of 60 nm is formed, where x is within the range from 0 to 1 and is varied with the ratio of the rare earth element sources. An amorphous rare earth oxide layer may be deposited by the ALD process. During the subsequent high temperature process, such as a gate deposition or a source and drain activation, the amorphous rare earth oxide layer may be crystallized and a stress may be induced.

Step S104: an active region is formed according to a standard process flow. For example, a channel region is formed in the semiconductor substrate, a source region and a drain region are formed on both sides of the channel region respectively, and a gate stack is formed on the channel region. A transistor having a rare earth oxide isolation layer in the channel length direction is finally formed after subsequent processes are finished.

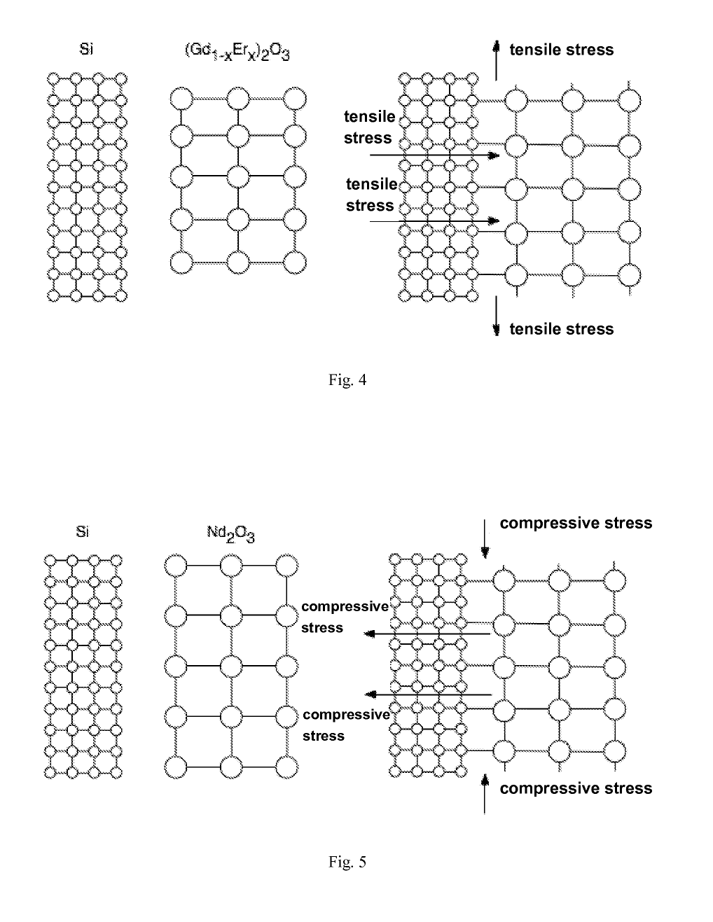

FIG. 4 is a schematic view of lattice structures of the first rare earth oxide layer and a side wall of the first trench of the semiconductor structure formed by the method according to Embodiment 1, in which a left drawing shows respective lattice structures of the first rare earth oxide layer and the side wall of the first trench, and a right drawing shows lattice structures of the first rare earth oxide layer and the side wall of the first trench when the stress is produced in the side wall of the first trench (i.e., the substrate region) by the first rare earth oxide layer. The material of the first rare earth oxide layer filled in the first trench is (Gd₁₋ₓErₓ)₂O₃, the lattice constant of which is slightly smaller than twice that of the material of the semiconductor substrate Si. When a filling material is grown in the first trench, the lattice constant of the filling material needs to be matched with that of the semiconductor substrate. Therefore, the lattice structure of the first rare earth oxide layer will be stretched in a vertical direction of the side wall of the first trench, thus generating a stretching effect which may produce the tensile stress in the source region, the drain region and the channel region in the channel length direction. Consequently, the carrier mobility of the channel region may be improved and the performance of the semiconductor device may be raised.

### Embodiment 2

Step S201: a semiconductor substrate is provided. In this embodiment, a material of the semiconductor substrate may be single crystal silicon.

Step S202: an active region is formed according to a standard process flow. For example, a channel region is formed in the semiconductor substrate, a source region and a drain region are formed on both sides of the channel region respectively, and a gate stack is formed on the channel region.

Step S203: a trench isolation region is predetermined in the semiconductor substrate and on both sides of the active region in a channel length direction, and then each first trench is formed by etching each trench isolation region. A depth of each first trench is determined according to an isolation requirement, which is generally matched with a width of the channel region. In this embodiment, the channel region and the first trench may be 60 nm in depth.

Step S204: a first rare earth oxide layer is filled in each first trench by ALD. With Nd(thd)₃ (tris(2,2,6,6-tetramethyl-3,5-heptanedionato)neodymium) as a metal precursor and with O₃ as an oxygen source, the rare earth oxide is grown by ALD at a temperature of 300° C., and after 1360 cycles, the first rare earth oxide layer Nd₂O₃ with a thickness of 60 nm is formed. An amorphous rare earth oxide layer may be deposited by the ALD process. During the subsequent high temperature process, such as a gate deposition or a source and drain activation, the amorphous rare earth oxide layer may be crystallized and a stress may be induced.

Step S205: a transistor having a rare earth oxide isolation layer in the channel length direction is finally formed after subsequent processes are finished.

FIG. 5 is a schematic view of lattice structures of the first rare earth oxide layer and a side wall of the first trench of the semiconductor structure formed by the method according to Embodiment 2, in which a left drawing shows respective lattice structures of the first rare earth oxide layer and the side wall of the first trench, and a right drawing shows lattice structures of the first rare earth oxide layer and the side wall of the first trench when the stress is produced in the side wall of the first trench (i.e., the substrate region) by the first rare earth oxide layer. The material of the first rare earth oxide layer filled in the first trench is Nd₂O₃, the lattice constant of which is slightly larger than twice that of the material of the semiconductor substrate Si. When a filling material is grown in the first trench, the lattice constant of the filling material needs to be matched with that of the semiconductor substrate. Therefore, the lattice structure of the first rare earth oxide layer will be compressed in a vertical direction of the side wall of the first trench, thus generating a compression effect which may produce the compressive stress in the source region, the drain region and the channel region in the channel length direction. Consequently, the carrier mobility of the channel region may be improved and the performance of the semiconductor device may be raised.

With the semiconductor structure and the method for forming the same according to an embodiment of the present disclosure, the rare earth oxide layer is formed in the trench isolation region of the semiconductor device as an isolation structure, thus producing the stress in a specific region of the semiconductor device and significantly improving the carrier mobility of the channel region. Moreover, by using a crystal characteristic of the rare earth oxide, a conventional and complicated method for filling an insulating material may be replaced by the crystal growth, thus greatly simplifying a process flow.

Reference throughout this specification to “an embodiment”, “some embodiments”, “one embodiment”, “an example”, “a specific example”, or “some examples” means that a particular feature, structure, material, or characteristic described in connection with the embodiment or example is included in at least one embodiment or example of the disclosure. Thus, the appearances of the phrases such as “in some embodiments”, “in one embodiment”, “in an embodiment”, “an example”, “a specific example”, or “some examples” in various places throughout this specification are not necessarily referring to the same embodiment or example of the disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, and modifications may be made in the embodiments without departing from spirit and principles of the disclosure. Such changes, alternatives, and modifications all fall into the scope of the claims and their equivalents.

1. A semiconductor structure, comprising:
a semiconductor substrate;
an active region formed in the semiconductor substrate, wherein the active region comprises:
a channel region, and a source region and a drain region formed on both sides of the channel region respectively; and
a first isolation trench formed in the semiconductor substrate and on both sides of the active region in a channel length direction, wherein a first rare earth oxide layer is formed in each first isolation trench to produce a stress in the channel region in the channel length direction.

2. The semiconductor structure according to claim 1, wherein a material of the semiconductor substrate comprises single crystal silicon, single crystal germanium, silicon-germanium, or any group III-V compound semiconductor.

3. The semiconductor structure according to claim 1, wherein a thickness of the first rare earth oxide layer is within a range from 10 nm to 500 nm.

4. The semiconductor structure according to claim 1, wherein a second isolation trench is formed in the semiconductor substrate and on both sides of the active region in a channel width direction.

5. The semiconductor structure according to claim 4, wherein a second rare earth oxide layer is formed in each second isolation trench to produce a stress in the channel region in the channel width direction, and the stress produced in the channel region by the second rare earth oxide layer and the stress produced in the channel region by the first rare earth oxide layer are opposite in type.

6. The semiconductor structure according to claim 5, wherein a material of each of the first rare earth oxide layer and the second rare earth oxide layer comprises any one of (Gd₁₋ₓErₓ)₂O₃, (Gd₁₋ₓNdₓ)₂O₃, (Er₁₋ₓNdₓ)₂O₃, (Pr₁₋ₓLaₓ)₂O₃, (Pr₁₋ₓNdₓ)₂O₃, (Pr₁₋ₓGdₓ)₂O₃, (Er₁₋ₓLaₓ)₂O₃, Er₂O₃, Gd₂O₃, Nd₂O₃, Pr₂O₃, La₂O₃ and a combination thereof, where x is within a range from 0 to 1.

7. The semiconductor structure according to claim 5, wherein the first rare earth oxide layer and the second rare earth oxide layer are formed by epitaxial growth.

8. A method for forming a semiconductor structure, comprising:
providing a semiconductor substrate;
forming an active region in the semiconductor substrate, wherein the active region comprises:
a channel region, and a source region and a drain region formed on both sides of the channel region respectively; and
before or after forming the active region, forming a first trench in the semiconductor substrate and on both sides of the active region in a channel length direction, and forming a first rare earth oxide layer in each first trench to produce a stress in the channel region in the channel length direction.

9. The method according to claim 8, wherein a material of the semiconductor substrate comprises single crystal silicon, single crystal germanium, silicon-germanium, or any group III-V compound semiconductor.

10. The method according to claim 8, wherein a thickness of the first rare earth oxide layer is within a range from 10 nm to 500 nm.

11. The method according to claim 8, before or after forming the active region, further comprising:
forming a second isolation trench in the semiconductor substrate and on both sides of the active region in a channel width direction; and
forming an isolation layer in each second isolation trench.

12. The method according to claim 11, wherein the isolation layer comprises a second rare earth oxide layer to produce a stress in the channel region in the channel width direction, and the stress produced in the channel region by the second rare earth oxide layer and the stress produced in the channel region by the first rare earth oxide layer are opposite in type.

13. The method according to claim 12, wherein a material of each of the first rare earth oxide layer and the second rare earth oxide layer comprises any one of (Gd₁₋ₓErₓ)₂O₃, (Gd₁₋ₓNdₓ)₂O₃, (Er₁₋ₓNdₓ)₂O₃, (Pr₁₋ₓLaₓ)₂O₃, (Pr₁₋ₓNdₓ)₂O₃, (Pr₁₋ₓGdₓ)₂O₃, (Er₁₋ₓLaₓ)₂O₃, Er₂O₃, Gd₂O₃, Nd₂O₃, Pr₂O₃, La₂O₃ and a combination thereof, where x is within a range from 0 to 1.

14. The method according to claim 12, wherein the first rare earth oxide layer and the second rare earth oxide layer are formed by epitaxial growth.

15. The method according to claim 14, wherein the epitaxial growth comprises atomic layer deposition, metal-organic chemical vapor deposition and molecular beam epitaxy.
